(19) United States
(12) Patent Application Publication
(10) Pub. No.: US 2011/0186103 A1
(43) Pub. Date: Aug. 4, 2011

(54) PHOTOELECTRIC CONVERSION ELEMENT, THIN-FILM SOLAR CELL, AND PHOTOELECTRIC CONVERSION ELEMENT MANUFACTURING METHOD

(75) Inventors: Hiroyuki KOBAYASHI, Kanagawa (JP); Toshiaki Fukunaga, Kanagawa (JP); Shinya Suzuki, Kanagawa (JP)

(73) Assignee: FUJIFILM Corporation, Tokyo (JP)

(21) Appl. No.: 13/017,965

(22) Filed: Jan. 31, 2011

(30) Foreign Application Priority Data
Feb. 1, 2010 (JP) 2010-020292
Jan. 18, 2011 (JP) 2011-007709

(51) Int. Cl. H01L 31/042; H01L 31/0216; H01L 31/0224

(52) U.S. Cl. 136/244; 136/256; 438/98; 257/E31.124

(57) ABSTRACT

A photoelectric conversion element includes a substrate with an insulation layer having a metallic substrate and an electrical insulation layer formed on a surface of the metallic substrate, a diffusion prevention layer formed on the electrical insulation layer, an alkali supply layer being electrically conductive and formed on the diffusion prevention layer, a lower electrode formed on the alkali supply layer, a photoelectric conversion layer comprising a compound semiconductor layer and formed on the lower electrode, and an upper electrode formed on the photoelectric conversion layer. The diffusion prevention layer prevents at least diffusion of alkali metal from the alkali supply layer to the substrate with the insulation layer.

### BACKGROUND OF THE INVENTION

The present invention relates to a photoelectric conversion element comprising a substrate with an insulation layer on which an insulation layer is provided, which has excellent withstand voltage characteristics and high conversion efficiency and is flexible, and to a thin-film solar cell using the photoelectric conversion element and to a photoelectric conversion element manufacturing method for manufacturing the photoelectric conversion element. In particular, the present invention relates to a photoelectric conversion element, a thin-film solar cell and a photoelectric conversion element manufacturing method wherein the amount of alkali metal supplied to the photoelectric conversion layer can be precisely controlled with good reproducibility, and conversion efficiency can be increased.

The substrates mainly used for thin-film solar cells are glass substrates. The glass substrate, however, breaks easily, requiring adequate care during handling, and has a limited application range owing to its lack of flexibility. Recently, solar cells are attracting attention as a power source for buildings such as residential housing. While increases in the solar cell size are essential for ensuring an adequate power supply, reductions in substrate weight have been desired with the increases in the solar cell surface area.

Nevertheless, when the glass substrate is made thinner in an attempt to reduce the substrate weight, the glass breaks more readily, resulting in demands for a substrate material that is shatterproof, flexible, and lighter than a glass substrate.

Additionally, the price of the glass substrate is relatively high compared to the price of a photoelectric conversion layer material of a solar cell, and thus an inexpensive substrate material that promotes more widespread use of solar cells is desired. When such a substrate material employs metal, difficulties arise in insulating the area between the substrate and solar cell material placed thereon. When resin is employed, the problem arises that the substrate cannot withstand high temperatures, such as the temperatures exceeding 400° C. that are required for solar cell formation.

That is, a glass substrate made of soda-lime glass, for example, exhibits adequate insulation properties but fails to achieve flexibility and low weight, and a metal substrate exhibits excellent flexibility and low weight, but fails to achieve adequate insulation properties. This makes it difficult to develop a substrate that offers insulation properties, flexibility, as well as low weight.

On the other hand, a copper-indium-gallium-selenide (CIGS) solar cell has been known to improve power generation efficiency when sodium (Na) (sodium ion: Na⁺) is diffused into the light absorbing layer (photoelectric conversion layer). In prior art, soda-lime glass is used as the substrate so that the Na contained in the soda-lime glass is diffused into the light absorbing layer.

However, when a metal sheet other than soda-lime glass is used as the substrate of the solar panel, the problem of having to supply Na separately to the light absorbing layer arises in addition to the above-described problem with insulation properties. For example, in JP 10-74966 A (Patent Document 1) and JP 10-74967 A (Patent Document 2), JP 9-55378 A (Patent Document 3), and JP 10-125941 A (Patent Document 4), Na₂Se, Na₂O, and Na₂S are respectively mixed vapor deposited. In JP 2005-117012 A (Patent Document 5), sodium phosphate is vapor-deposited on molybdenum (Mo). In JP 2006-210424 A (Patent Document 6), an aqueous solution containing sodium molybdate is deposited on a precursor. In JP 2003-318424 A (Patent Document 7), Na₂S and Na₂Se are formed to supply Na and, in JP 2005-86167 A (Patent Document 8), Na₃AlF₆ is formed between Mo and the substrate and/or the light absorbing layer to supply Na. In JP 8-222750 A (Patent Document 9), Na₂S or Na₂Se is precipitated onto Mo electrodes, and in JP 2004-158556 A (Patent Document 10) and JP 2004-79858 A (Patent Document 11), NaF is coated on Mo to supply Na.

Additionally, in JP 2006-80370 A (Patent Document 12), when a metal substrate is used as a substrate for a solar cell using a chalcopyrite semiconductor, a glass layer is formed on the metal substrate as an insulation layer between the metal substrate and photoelectric conversion layer, thereby increasing the withstand voltage of the substrate and providing the substrate at low cost.

In JP 2009-267332 A (Patent Document 13), a first insulating oxide film is formed on a metal substrate by anodizing, and a second insulating film that contains alkali metal ions is formed on this first insulating oxide film to form the solar cell substrate.

In JP 4022577 B (Patent Document 14), when a solar cell comprising a chalcopyrite absorbing layer is formed on a glass substrate, an alkali metal element selected from Na, K, and Li, or a compound thereof, is added by doping before or during the manufacture of the absorbing layer. Then, by a diffusion intercepting layer that is selected from TiN, Al₂O₃, SiO₂, Si₃N₄, ZrO₂, or TiO₂ and arranged between the substrate and the chalcopyrite absorbing layer, additional diffusion of the alkali metal ions from the substrate into the absorbing layer during the manufacturing process is prevented, and the concentration of the alkali metal element within the absorbing layer is adjusted.

That is, in Patent Document 14, an attempt is made to separately supply an alkali metal element (ion), such as Na, of a solar cell comprising a chalcopyrite absorbing layer while controlling the supplied volume, rather than supplying the alkali metal element (ion) from the substrate side. In a case where a glass substrate is used from a cost standpoint, since a high volume of alkali metal ions diffuses from the glass substrate, sometimes resulting in a loss in properties, alkali metal ions are supplied separately and not from the glass substrate for the sake of controllability. Thus, in Patent Document 14, controllability is controlled by the volume of Na supplied. This controllability is the same for substrates other than glass substrates as well; even if the substrate is a conductive substrate such as a metal substrate that does not contain an alkali metal, Na is supplied from an external source similar to the above.

In JP 3503824 B (Patent Document 15), a Na supply layer is provided on a conductive substrate, and Na is supplied to the light absorbing layer through an electrode layer formed thereon.

Additionally, in Applied Physics Letters, 93, 124105 (2008) (Non-Patent Document 1), a thin soda-lime glass film is formed on both Ti foil and a zirconia substrate, and molybdenum back electrodes are formed thereon. Non-Patent Document 1 discloses a thickness of the thin soda-lime glass film that maximizes efficiency in a case where Ti foil and a zirconia substrate are used.

In Thin Solid Films, 515 (2007), p. 5876 (Non-Patent Document 2), addition of Na to a CIGS film using a non-Na-containing substrate is disclosed as a configuration of No or No which contains Na on an alumina substrate.

### SUMMARY OF THE INVENTION

As described above, when a metal plate, etc., other than soda-lime glass (SLG) is used as the solar cell substrate, the problem arises that an alkali metal such as Na must be supplied separately in order to improve the conversion efficiency of the photoelectric conversion layer. For example, even with an anodized aluminum substrate, an Na supply layer needs to be formed in order to diffuse Na at an appropriate concentration into the CIGS photoelectric conversion layer formed on the substrate, improve the CIGS crystal quality, and enhance the conversion efficiency.

Nevertheless, as in the prior art of Patent Documents 1 to 11, when Na is to be diffused into the photoelectric conversion layer and a layer of Na is formed on the back electrodes by vapor deposition, sputtering, or coating, the Na layer formed is altered due to deliquescence, etc., causing the layer to readily delaminate.

Additionally, while a glass layer serving as the insulation layer is formed when a metal substrate is to be used as in Patent Document 12, a great difference in a linear thermal expansion coefficients of the metal substrate and photoelectric conversion layer results in delamination due to the high temperature during film formation, and a small difference in the thermal expansion coefficients of the metal substrate and the photoelectric conversion layer results in failure to achieve adequate withstand voltage since the thickness of the glass layer is intrinsically thin, even though the material may be able to withstand high temperatures. Further, since the glass layer contains an alkali metal ion such as Na, this alkali metal ion diffuses into the photoelectric conversion layer during formation thereof, but has the disadvantage of simultaneously diffusing into the metal substrate as well. As a result, the metal substrate is altered and delamination occurs, making it no longer possible to diffuse the necessary amount of Na into the photoelectric conversion layer.

Further, with the solar cell substrate disclosed in Patent Document 13, the alkali metal ions diffuse into the metal substrate side as well during film formation, causing inadequate supply of the alkali metal ions to the GIGS photoelectric conversion layer and failure to achieve a high photoelectric conversion efficiency; and when Na ions diffuse into the anodized film serving as the first insulating oxide film, the problem arises that the anodized film becomes altered.

Further, while Patent Document 14 discloses that, when a glass substrate is used as the substrate of a solar cell comprising a chalcopyrite absorbing layer, a diffusion intercepting layer that intercepts additional diffusion of the alkali metal ions from the substrate to within the absorbing layer during manufacturing is disposed between the substrate and the chalcopyrite absorbing layer, the alkali metal requires doping by sputtering, etc., before or during the manufacture of the absorbing layer, and the doped alkali metal needs to be precipitated as an alkali metal compound on the back electrodes, i.e., rear electrodes (hereinafter “back electrodes”), in order to supply the alkali metal from the back electrodes during the manufacture of the absorbing layer after the back electrodes are formed. Further, the effect of the diffusion intercepting layer in Patent Document 14 is problematic in that it merely inhibits diffusion of the alkali metal (Na) from the glass substrate, and the disclosed technique of precipitation on the back electrodes is not preferred since it causes delamination and alteration of the back electrodes.

Note, however, that in a case where a conductive substrate that does not contain an alkali metal is used as the substrate, an additional insulation layer is required between the back electrodes and substrate. In such a case, while the substrate does not serve as the alkali metal supply source, thereby eliminating the need to provide a diffusion intercepting layer, the problem arises that the alkali metal must be similarly separately provided. Furthermore, while delamination occurs at high temperatures and a high-performance photoelectric conversion element cannot be achieved when a conductive substrate is used and the thermal expansion coefficients of the substrate and photoelectric conversion layer do not match, the conductive substrate disclosed in Patent Document 14 is problematic in that delamination may occur when the thermal expansion coefficients of the conductive substrate and photoelectric conversion layer, or the thermal expansion coefficients of the conductive substrate, photoelectric conversion layer and an additional insulation layer therebetween, deviate from one another.

Further, in the method of Na supply to the photoelectric conversion layer disclosed in Patent Document 15, Na is diffused into the substrate as well, requiring the supply layer to be sufficiently thick in order to ensure that a sufficient amount of Na is diffused into the photoelectric conversion layer side. When the thickness is increased, however, the problem arises that delamination occurs from this supply layer.

Furthermore, the Ti foil substrate disclosed in Non-Patent Document 1 makes it difficult to maintain insulation properties, resulting in the disadvantage that a solar cell having an integrated structure cannot be formed. Further, with the zirconia substrate disclosed in Non-Patent Document 1, there is the disadvantage that a flexible photoelectric conversion element and solar cell cannot be formed, in addition to the disadvantage of high cost.

Also, in Non-Patent Document 2, there is the problem that, because Na diffuses into the substrate as well, a sufficient quantity of Na on the level of an SLG substrate cannot be supplied to the CIGS film side and conversion efficiency is poor even if the Na-doped Mo film is thick.

Further, in general, the interface areas such as that of the insulation layer and back electrode layer or the photoelectric conversion material layer are problematic in that delamination readily occurs due a difference in thermal expansion coefficients.

In particular, with an anodized aluminum substrate, the diffused Na alters the anodized film, causing an increase in strain after growth of the CIGS, and delamination of the CIGS.

Additionally, to decrease the cost of the solar cell and increase productivity, a method of diffusing the alkali metal from the substrate into the photoelectric conversion layer within the short film formation period is required.

It is therefore an objective of the present invention to solve the above-described problems based on prior art and provide a photoelectric conversion element that is light in weight, flexible, superior in an electrical insulation properties, and capable of sufficiently maintaining and controlling the precision and reproducibility of the amount of alkali metal supplied to the photoelectric conversion layer and increasing photoelectric conversion efficiency; a thin-film solar cell that uses the photoelectric conversion element having the above features; and a manufacturing method of a photoelectric conversion element that is capable of efficiently manufacturing the photoelectric conversion element.

Additionally, it is also an objective of the present invention to provide a photoelectric conversion element that exhibits excellent adhesion between the insulation layer and the layer formed thereon and has preferred withstand voltage characteristics and heat resistance; a thin-film solar cell that uses the photoelectric conversion element having the above features; and a manufacturing method of a photoelectric conversion element that is capable of efficiently manufacturing the photoelectric conversion element.

Additionally, it is also an objective of the present invention to provide a photoelectric conversion element and a thin-film solar cell that are capable of being manufactured with improved productivity; and a manufacturing method of a photoelectric conversion element that is capable of manufacturing the photoelectric conversion element with the improved productivity.

To achieve the above objective, the first aspect of the present invention provides a photoelectric conversion element comprising: a substrate with an insulation layer made of a metallic substrate and an electrical insulation layer formed on the surface of the metallic substrate, a diffusion prevention layer formed on the electrical insulation layer, an alkali supply layer that is electrically conductive and is formed on the diffusion prevention layer, a lower electrode formed on the alkali supply layer, a photoelectric conversion layer that is made of a compound semiconductor layer and is formed on the lower electrode, and an upper electrode that is formed on the photoelectric conversion layer, wherein the diffusion prevention layer prevents at least diffusion of the alkali metal from the alkali supply layer to the substrate with an insulation layer.

Further, to achieve the above objective, the second aspect of the present invention provides a photoelectric conversion element manufacturing method comprising the steps of: forming an electrical insulation layer on the surface of a metallic substrate and obtaining a substrate with an insulation layer; forming, on the electrical insulation layer, a diffusion prevention layer that prevents at least diffusion of the alkali metal into the substrate with an insulation layer; forming a conductive alkali supply layer on the diffusion prevention layer; forming a lower electrode on the alkali supply layer; forming a photoelectric conversion layer on the lower electrode; and forming an upper electrode on the photoelectric conversion layer.

The metallic substrate is a laminated plate wherein a metal base and an Al base are layered and unified, and the process wherein the substrate with an insulation layer is obtained is preferably a process wherein the Al base is subjected to an anodizing treatment to form an anodized film on the surface of the Al base.

In each aspect of the present invention, the compound semiconductor is preferably composed of at least one kind of compound semiconductor of a chalcopyrite structure, more preferably at least one kind of compound semiconductor composed of at least a group Ib element, a group IIIb element, and a group VIb element, and even more preferably at least one kind of compound semiconductor composed of at least one kind of group Ib element selected from the group consisting of Cu and Ag, at least one kind of group IIIb element selected from the group consisting of Al, Ga, and In, and at least one kind of group VIb element selected from the group consisting of S, Se, and Te.

Further, the diffusion prevention layer is preferably made of nitride. The nitride is preferably an electrical insulator, and comprises more preferably at least one kind of TiN, ZrN, BN, and AlN, and most preferably AlN.

Further, the diffusion prevention layer preferably has a thickness of 10 nm to 200 nm, and more preferably 10 nm to 100 nm.

Further, the photoelectric conversion layer is preferably split into a plurality of elements by a plurality of opening grooves, and the plurality of elements is preferably electrically connected in series.

Further, the alkali supply layer is preferably made of Mo that contains Na and/or an Na compound. Preferably the Na compound is NaF or Na₂MoO₄.

Further, the alkali supply layer is preferably a layer formed by sputtering. Further, the thickness of the alkali supply layer is preferably 100 nm to 800 nm, and more preferably 100 nm to 400 nm.

Further, the lower electrode is made of Mo, and the thickness thereof is preferably 200 nm to 600 nm, and more preferably 200 nm to 400 nm.

Further, the metallic substrate is preferably a laminated plate wherein a metal base and Al base are layered and unified, and more preferably a laminated plate wherein the metal base and the Al base are integrated by compression bonding.

Further, the metal base is preferably a steel material, an alloy steel material, Ti foil, or a dual-layer base made of Ti foil and a steel material; the alloy steel material is preferably made of carbon steel and a ferrite stainless steel; and the thermal expansion coefficient difference between the metal base and the photoelectric conversion layer is preferably less than 3×10⁻⁶/° C., and more preferably less than 1×10⁻⁶/° C. Further, the electrical insulation layer is preferably an anodized film of aluminum.

Further, the metallic substrate preferably comprises a laminated plate wherein carbon steel or an alloy steel material made of ferrite stainless steel is integrated with an Al base by compression bonding, the lower electrode is preferably made of Mo, and the photoelectric conversion layer is preferably a layer comprising as its main component at least one kind of compound semiconductor composed of a group Ib element, a group IIIb element, and a group VIb element.

Further, the anodized film preferably has a porous structure.

Additionally, to achieve the above objective, the third aspect of the present invention is to provide a thin-film solar cell comprising the photoelectric conversion element of the above first aspect.

According to the present invention, by forming a diffusion prevention layer on an electrical insulation layer of a substrate with an insulation layer and forming a conductive alkali supply layer on the diffusion prevention layer, the diffused amount of alkali metal element ions or alkali earth metal element ions (represented by alkali metals hereinafter) into the photoelectric conversion layer can be increased, and as a result, the supplied quantity thereof can be increased, and can be controlled precisely and with good reproducibility. For this reason, a photoelectric conversion element with high photoelectric conversion efficiency can be obtained.

Further, in the present invention, by using an alkali supply layer that is conductive, formation by, for example, DC sputtering is possible, and compared to insulating alkali supply layers, it can be formed at a higher deposition rate and productivity can be improved.

Furthermore, in the present invention, an electrical insulation layer is formed on the substrate with an insulation layer, and the diffusion prevention layer is made of an insulator, making it possible to further improve the insulation properties (withstand voltage characteristics) of the substrate.

Further, according to the present invention, it is possible to make the thermal expansion coefficients of the diffusion prevention layer, metallic substrate, and photoelectric conversion layer uniform and thus maintain and improve the adhesion between the diffusion prevention layer, metallic substrate, and photoelectric conversion layer, thereby preventing delamination of the metallic substrate and photoelectric conversion layer.

Further, according to the present invention, it is possible to use a metallic substrate that has a flexible insulation layer and comprises an aluminum (Al) base containing Al as its main component, making it possible to achieve a substrate having characteristics that result in minimal strain and no cracking even at high temperatures. Therefore, according to the present invention, it is possible to make it possible to achieve a photoelectric conversion element that is light in weight, flexible, superior in an electrical insulation properties, and capable of increasing photoelectric conversion efficiency.

### BRIEF DESCRIPTION OF THE DRAWINGS

FIG. 1 is a schematic cross-sectional view illustrating a thin-film solar cell comprising a photoelectric conversion element according to an embodiment of the present invention.

FIG. 2A is a schematic cross-sectional view illustrating a substrate used in a thin-film solar cell comprising a photoelectric conversion element according to an embodiment of the present invention, and FIG. 2B is a schematic cross-sectional view illustrating another example of a substrate used in a thin-film solar cell comprising a photoelectric conversion element according to an embodiment of the present invention.

### DETAILED DESCRIPTION OF THE INVENTION

The photoelectric conversion element, thin-film solar cell, and photoelectric conversion element manufacturing method of the present invention will now be described based on preferred embodiments illustrated in the accompanying drawings.

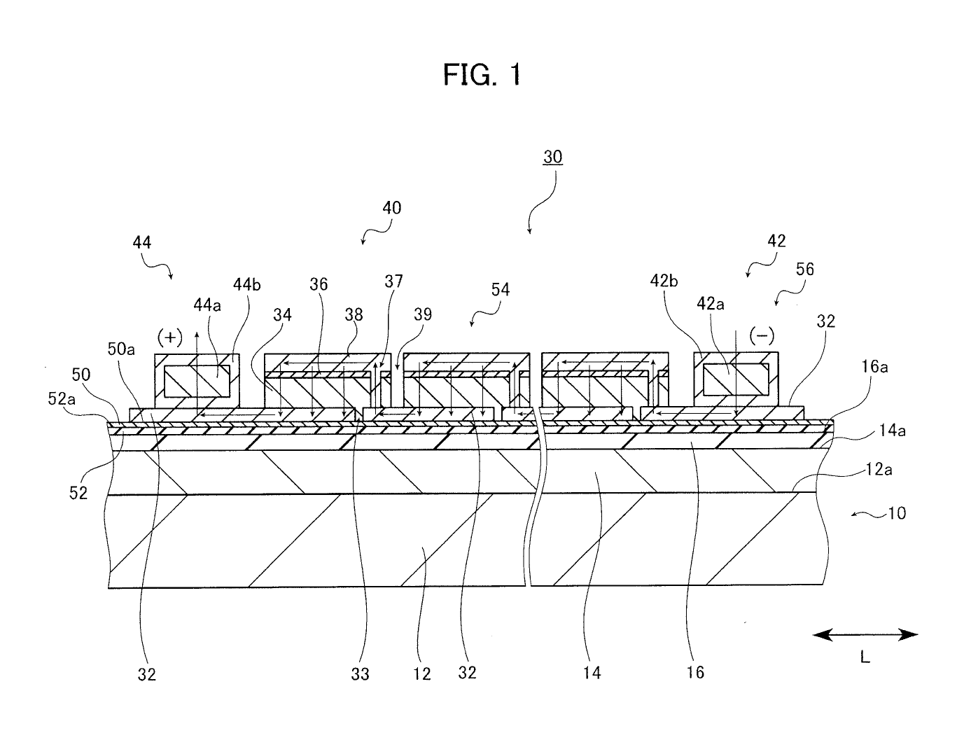

FIG. 1 is a schematic cross-sectional View illustrating a thin-film solar cell comprising a photoelectric conversion element according to an embodiment of the present invention.

A thin-film solar cell 30 of the embodiment shown in FIG. 1 is used in a solar cell module or a solar cell sub-module constituting this solar cell module. The thin-film solar cell 30 comprises, for example, a substrate 10 with an insulation layer (hereinafter “substrate 10”) comprising a grounded metallic substrate 15 of a substantially rectangular shape and an electrical insulation layer 16 formed on the metallic substrate 15, a diffusion prevention layer 52 formed on the insulation layer 16, an alkali supply layer 50 formed on the diffusion prevention layer 52, a plurality of power generating cells (solar cells) 54 connected in series and formed on the alkali supply layer 50, and a power generating layer 56 comprising a first conductive member 42 connected to one and a second conductive member 44 connected to another of the plurality of power generating cells 54. Note that the body comprising one of the power generating cells 54, the corresponding substrate 10, the diffusion prevention layer 52, and the alkali supply layer 50 is herein called a photoelectric conversion element 40, but the thin-film solar cell 30 itself shown in FIG. 1 may be called a photoelectric conversion element.

First, the substrate used in the thin-film solar cell comprising a photoelectric conversion element according to an embodiment of the present invention will be described.

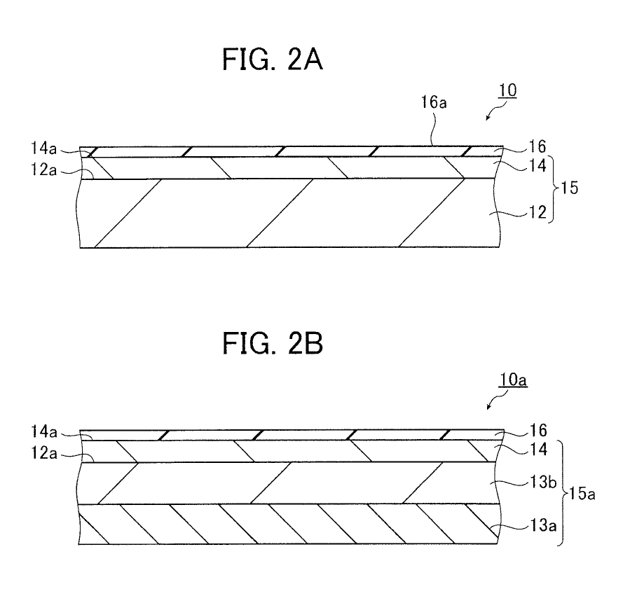

FIG. 2A is a schematic cross-sectional view illustrating a substrate used in a thin-film solar cell comprising a photoelectric conversion element according to an embodiment of the present invention shown in FIG. 1, and FIG. 2B is a schematic cross-sectional view illustrating another example of a substrate used in a thin-film solar cell comprising a photoelectric conversion element according to an embodiment of the present invention.

As shown in FIG. 2A, the substrate 10 is a substrate with an insulation layer comprising the metallic substrate 15 formed of a metal base 12 and an aluminum base 14 (hereinafter “Al base 14”) that has aluminum as its main component, and the insulation layer 16.

In the substrate 10, the Al base 14 is formed on a surface 12a of the metal base 12 to constitute the metallic substrate 15, and the insulation layer 16 is formed on a surface 14a of the Al base 14 of the metallic substrate 15. Further, the metallic substrate 15 is a substrate wherein the metal base 12 and the Al base 14 are layered and unified, i.e., an Al clad base or an Al clad substrate.

The substrate 10 of the embodiment is used as a substrate of a photoelectric conversion element and thin-film solar cell, and is flat in shape, for example. The shape and size of the substrate 10 are suitably determined in accordance with the size, etc., of the photoelectric conversion element and thin-film solar cell in which it is applied. When used in a thin-film solar cell, the substrate 10 is square or rectangular in shape, with the length of one side exceeding 1 m, for example.

In the substrate 10, the material used for the metal base 12 is a flat-shaped or foil-shaped metal material, examples including a steel material such as a carbon steel or ferrite stainless steel.

A steel material used for the metal base 12 exhibits greater strength in temperatures of 300° C. and higher than aluminum alloy, achieving a predetermined heat resistance in the substrate 10.

The carbon steel used for the metal base 12 is a carbon steel for mechanical structures having a carbon content of 0.6 mass % or less, for example. Examples of materials used as the carbon steel for a mechanical structure include materials generally referred to as SC materials.

Further, the materials that can be used as the ferrite stainless steel include SUS430, SUS405, SUS410, SUS436, and SUS444.

Examples of materials that can be used as the steel material in addition to the above include materials generally referred to as SPCC materials (cold-rolled carbon steel sheets).

Note that, other than the above, the metal base 12 may be made of a kovar alloy, titanium, or a titanium alloy. The material used as titanium is pure titanium, and the materials used as the titanium alloy is Ti-6Al-4V and Ti-15V-3Cr-3Al-3Sn, which are wrought alloys. These metals also are used in a flat shape or foil shape.

The metal base 12 is preferably a metal or alloy that has a linear thermal expansion coefficient that is lower than aluminum and aluminum alloy, exhibits high rigidity, and achieves high heat resistance.

The thickness of the metal base 12 affects flexibility, and is thus preferably thin, within a range not associated with an excessive lack of rigidity.

In the substrate 10 of this embodiment, the thickness of the metal base 12 is, for example, 10-800 μm, preferably 30-300 μm. More preferably, the thickness is 50-150 μm. The reduced thickness of the metal base 12 is also preferred from a raw material cost standpoint.

The metal base 12 is a material that has flexibility. That is, for flexibility, the metal base 12 employed is preferably ferrite stainless steel.

The Al base 14 comprises aluminum (Al) as its main component, meaning that the aluminum content is at least 90 massa.

Examples of materials used as the Al base 14 include aluminum and aluminum alloy. The aluminum or aluminum alloy used for the Al base 14 preferably does not contain any unnecessary intermetallic compounds. Specifically, aluminum with a purity of at least 99 mass % which contains few impurities is preferred. For example, aluminum with a purity of 99.99 mass %, aluminum with a purity of 99.96 mass %, aluminum with a purity of 99.9 mass %, aluminum with a purity of 99.85 mass %, aluminum with a purity of 99.7 mass %, and aluminum with a purity of 99.5 mass % are preferred. Also, aluminum alloys to which elements that tend not to form intermetallic compounds have been added may be used. Examples include an aluminum alloy formed by adding magnesium to 99.9 mass % Al in an amount of 2.0 mass % to 7.0 massa. Other than magnesium, elements with a high solid solubility limit, such as copper and silicon, may be added.

Increasing the purity of the aluminum of the Al base 14 makes it possible to avoid occurring intermetallic compounds, which cause deposits, and increase the integrity of the insulation layer 16. In a case where an aluminum alloy is anodized, the possibility exists that intermetallic compounds will become the origin of poor insulation; and this possibility increases as the amount of intermetallic compounds increases.

The thickness of the Al base 14 is, for example, 5-150 μm, and preferably 10-100 μm. It is more preferably 20-50 μm.

The Al base 14 has a surface roughness in terms of, for example, arithmetic mean roughness Ra is 1 μm or less. This surface roughness is preferably 0.5 μm or less and more preferably 0.1 μm or less.

Note that the front surface of the Al base 14 may be mirror-finished. This mirror finish is formed using, for example, the method described in JP 4212641 B, JP 2003-341696 A, JP 7-331379 A, JP 2007-196250 A, or JP 2000-223205 A.

In the substrate 10, the insulation layer 16 is for insulation and preventing damage from mechanical impact during handling. This insulation layer 16 is made of an anodized film[aluminum anodized film (aluminum film)].

The insulation layer 16 is not limited to an anodized film, and may be formed by vapor deposition method, sputtering method or CVD method.

The insulation layer 16 preferably has a thickness of 5 μm or more, and more preferably 10 μm or more. An excessively thick insulation layer 16 is not preferred because flexibility is reduced and cost and time are required for forming the insulation layer 16. In practice, the thickness of the insulation layer 16 is 50 μm or less, preferably 30 μm or less. Therefore, the preferred thickness of the insulation layer 16 is 0.5-50 μm.

The front surface 18a of the insulation layer 16 has a surface roughness in terms of, for example, the arithmetic mean roughness Ra is 1 μm or less, preferably 0.5 μm or less, and more preferably 0.1 μm or less.

The strength of the substrate 10 requires a tensile strength of at least 5 MPa during heat treatment at 500° C. or higher, and is therefore preferably at least 10 MPa.

Further, to ensure that creep deformation does not occur during heat treatment at 500° C. or higher, the strength that allows up to 0.1% plastic deformation when the material is maintained for 10 minutes at 500° C. is preferably at least 0.2 MPa, more preferably at least 0.4 MPa, and even more preferably at least 1 MPa.

The substrate 10 includes the metal base 12, the Al base 14, and the insulation layer 16 which are all made of flexible materials, and is therefore flexible as a whole. An alkali supply layer, a diffusion prevention layer, a back electrodes serving as a lower electrodes, the photoelectric conversion layer, and the transparent electrodes serving as the upper electrodes can be thus formed on the insulation layer 16 side of the substrate 10 by, for example, a roll-to-roll process.

Further, in this embodiment, the substrate 10 serves as the substrate with an insulation layer comprising the metallic substrate 15, wherein the metal base 12 and the Al base 14 are laminated and unified, and the insulation layer 16 that is formed on the surface 14a of the Al base 14 of the metallic substrate 15, making it possible to maintain high insulation properties and high strength even when subjected to a film deposition process at a temperature of 500° C. or higher, for example, enabling the various films to be formed by, for example, a roll-to-roll process at a high temperature of 500° C. or higher.

Further, while the substrate 10 of the embodiment comprises a metallic substrate 15 having a dual-layer structure of the metal base 12 and the Al base 14, the present invention permits at least one layer of metal base 12, and is not limited to one layer, allowing a plurality of layers.

As in a substrate 10a shown in FIG. 2B, the metal base may have a dual-layer structure comprising a first metal base 13a and a second metal base 13b, for example.

In such a case, the first metal base 13a is made of titanium or a titanium alloy, for example, and the second metal base 13b is made of a steel material similar to the metal base 12. Note that the second metal base 13b may be made of titanium or a titanium alloy, and the first metal base 13a may be made of a steel material similar to the metal base 12.

Further, the substrate may be configured such that the Al base 14 is formed on the front surface 12a and the back surface of the metal base 12, and the insulation layer 16 is formed on the surface 14a of each Al base 14. In this case, Al bases 14 and insulation layers 16 are formed symmetrically centered around the metal base 12. Note that the metal base 12 and two Al bases 14 are laminated and unified to form a metallic substrate.

Next, the manufacturing method of the substrate 10 of the embodiment will be described.

First, the metal base 12 is prepared. This metal base 12 is formed to a predetermined shape and size suitable to the size of the substrate 10 to be formed.

Then, the Al base 14 is formed on the surface 12a of the metal base 12. The metallic substrate 15 is thus formed.

The method of forming the Al base 14 on the surface 12a of the metal base 12 is not particularly limited as long as integral connection between the metal base 12 and the Al base 14 that can ensure the adhesion therebetween is achieved. The formation method of the Al base 14 used includes, for example, a vapor deposition method, vapor phase method such as sputtering, plating method, and pressurizing and bonding after surface cleaning. Pressure-bonding by rolling is preferably used to form the Al base 14 in terms of the cost and mass production capability.

Note that both the surface 12a and the back surface of the metal base 12 may form the Al base 14, as described above.

Next, the insulation layer 16 is formed on the surface 14a of the Al base 14 of the metallic substrate 15. The substrate 10 is thus obtained. The method of forming the anodized film serving as the insulation layer 16 is described below.

The anodized film serving as the insulation layer 16 can be formed by immersing the metal base 12 serving as the anode in an electrolytic solution together with the cathode and applying voltage between the anode and the cathode. In the case, the metal base 12 forms a local cell with the Al base 14 upon contact with the electrolytic solution and therefore the metal base 12 contacting the electrolytic solution is to be masked and isolated using a masking film (not shown). That is, the end surface and the back surface of the metal base 12 other than the surface 14a of the Al base 14 need to be isolated using a masking film (not shown).

Where necessary, pre-anodization may include steps of subjecting the surface of the Al base 14 to cleaning and polishing/smoothing processes.

Carbon or aluminum or the like is used for the cathode in anodization. As the electrolyte, an acidic electrolytic solution containing one or more kinds of acids such as sulfuric acid, phosphoric acid, chromic acid, oxalic acid, sulfamic acid, benzenesulfonic acid and amidosulfonic acid is used. The anodization conditions vary with the type of electrolyte used and are not particularly limited. As an example, appropriate anodization conditions are an electrolyte concentration of 1-80 mass %, a solution temperature of 5-70° C., a current density of 0.005-0.60 A/cm², a voltage of 1-200 V and an electrolysis time of 3-500 minutes. The electrolyte is preferably sulfuric acid, phosphoric acid, oxalic acid or a mixture thereof. When an electrolyte as described above is used, an electrolyte concentration of 4-30 mass %, a solution temperature of 10-30° C., a current density of 0.002-0.30 A/cm² and a voltage of 20-100 V are preferred.

During the anodization treatment, an oxidation reaction proceeds substantially in the vertical direction from the surface 14a of the Al base 14 to form the anodized film on the surface 14a of the Al base 14. In cases where any of the above electrolytic solutions is used, the anodized film is of a porous type in which a large number of fine columns in the shape of a substantially regular hexagon as seen from above are arranged without gaps, and a micropore having a rounded bottom is formed at the core of each fine column, the bottom of each fine column having a barrier layer with a thickness of typically 0.02-0.1 μm.

The anodized film having such a porous structure has a low Young's modulus compared to a single aluminum oxide film of a non-porous structure, and high crack resistance due to its flexural capacity and thermal expansion difference at high temperatures.

Note that a dense anodized film (non-porous aluminum oxide single film), rather than an anodized film in which porous fine columns are arranged, is obtained by electrolytic treatment in a neutral electrolytic solution such as boric acid without using an acidic electrolytic solution. An anodized film in which the thickness of the barrier layer has been increased by pore filling may be formed by again performing electrolysis treatment with a neutral electrolytic solution after the porous anodized film is produced with an acidic electrolytic solution. The insulation properties of the film may be further increased by increasing the thickness of the barrier layer.

The electrolytic solution used in the anodization treatment is preferably a sulfuric acid aqueous solution or oxalic acid solution. Oxalic acid aqueous solution is excellent for soundness of the anodized film, and sulfuric acid aqueous solution is excellent for mass producibility by a continuous process.

As described above, the anodized film serving as the insulation layer 16 preferably has a thickness of 0.5 to 50 μm. The thickness can be controlled by the electrolysis time and the magnitudes of the current and voltage in constant current electrolysis or constant voltage electrolysis.

In cases where it is desired to increase the insulation properties of the insulation layer 16 formed by anodization, pore sealing treatment can be performed using, for example, a boric acid solution. The pore sealing treatment is a treatment for sealing and/or filling pores and/or voids.

Anodization treatment can be performed using, for example, a known so-called roll-to-roll process anodization apparatus.

Next, after the anodizing treatment, the masking film (not shown) is peeled off. The substrate 10 can be thus formed.

The substrate 10 of this embodiment may employ the metallic substrate 15 comprising the Al base 14 having aluminum (Al) as its main component and a flexible anodized film serving as the insulation layer 16, thereby providing the characteristics of minimal strain and no cracking at high temperatures.

Next, the photoelectric conversion element 40 of the thin-film solar cell 30 of the embodiment shown in FIG. 1 will be described.

In the thin-film solar cell 30 (thin-film solar cell sub-module, for example) of the embodiment, the diffusion prevention layer 52 is formed on a surface of the aforementioned substrate 10, that is, a surface 16a of the insulation layer 16, and the conductive alkali supply layer 50 is formed on a surface 52a of this diffusion prevention layer 52.

The thin-film solar cell 30 includes a plurality of the photoelectric conversion elements 40, the first conductive member 42, and the second conductive member 44.

The photoelectric conversion element 40 makes up the thin-film solar cell 30 and comprises the substrate 10, the diffusion prevention layer 52, the alkali supply layer 50, and the power generating cell (solar cell) 54 comprising a back electrodes 32, a photoelectric conversion layers 34, a buffer layers 36, and a transparent electrode 38.

As described above, the diffusion prevention layer 52 is formed on the surface 16a of the insulation layer 16, and the alkali supply layer 50 is formed on this diffusion prevention layer 52. The back electrodes 32 of the power generating cell 54, the photoelectric conversion layers 34, the buffer layers 36, and the transparent electrode 38 is layered in that order on a surface 50a of the alkali supply layer 50.

The back electrodes 32 are formed on the surface 50a of the conductive alkali supply layer 50 so as to share a separation groove (P1) 33 with the adjacent back electrodes 32. The photoelectric conversion layer 34 is formed on the back electrodes 32 so as to fill the separation grooves (P1) 33. The buffer layer 36 is formed on the front surface of the photoelectric conversion layer 34. The photoelectric conversion layers 34 and the buffer layers 36 are separated from adjacent photoelectric conversion layers 34 and adjacent buffer layers 36 by grooves (P2) 37 which reach the back electrodes 32. The grooves (P2) 37 are formed in different positions from those of the separation grooves (P1) 33 that separate the back electrodes 32.

The transparent electrode 38 is formed on the surface of the buffer layer 36 so as to fill the grooves (P2) 37.

Opening grooves (P3) 39 are formed so as to reach the back electrodes 32 by penetrating through the transparent electrode 38, the buffer layer 36, and the photoelectric conversion layer 34. In the thin-film solar cell 30, the respective photoelectric conversion elements 40 are electrically connected in series in a longitudinal direction L of the substrate 10 through the back electrodes 32 and the transparent electrode 38.

The photoelectric conversion elements 40 of this embodiment are so-called integrated type photoelectric conversion elements (solar cells) and have a configuration such, for example, that the back electrodes 32 are molybdenum electrodes, the photoelectric conversion layers 34 are formed of a semiconducting compound having a photoelectric conversion function such as a CIGS layer, the buffer layers 36 are formed of CdS, and the transparent electrode 38 is formed of ZnO.

Note that the photoelectric conversion elements 40 are formed so as to extend in the width direction perpendicular to the longitudinal direction L of the substrate 10. Therefore, the back electrodes 32 also extend in the width direction of the substrate 10.

As illustrated in FIG. 1, the first conductive member 42 is connected to the rightmost back electrode 32. The first conductive member 42 is provided to collect the output from a negative electrode as will be described below onto the outside. Although a photoelectric conversion element 40 is formed on the rightmost back electrode 32, that photoelectric conversion element 40 is removed by, for example, laser scribing or mechanical scribing to expose the back electrode 32.

The first conductive member 42 is, for example, a member in the shape of an elongated strip which extends substantially linearly in the width direction of the substrate 10, and is connected to the rightmost back electrode 32. As shown in FIG. 1, the first conductive member 42 has, for example, a copper ribbon 42a covered with a coating material 42b made of an alloy of indium and copper. The first conductive member 42 is connected to the back electrodes 32 by, for example, ultrasonic soldering.

The second conductive member 44 is provided to collect the output from the positive electrode to be described later. Like the first conductive member 42, the second conductive member 44 is a member in the shape of an elongated strip which extends substantially linearly in the width direction of the substrate 10, and is connected to the leftmost back electrode 32. Although a photoelectric conversion element 40 is formed on the leftmost back electrode 32, that photoelectric conversion element 40 is removed by, for example, laser scribing or mechanical scribing, to expose the back electrode 32.

The second conductive member 44 is composed similarly to the first conductive member 42 and has, for example, a copper ribbon 44a covered with a coating material 44b made of an alloy of indium and copper.

The first conductive member 42 and the second conductive member 44 may be formed of a tin-plated copper ribbon. Furthermore, the method of connection of the first conductive member 42 and the second conductive member 44 is not limited to ultrasonic soldering, and they may be connected by such means as, for example, a conductive adhesive or conductive tape.

The photoelectric conversion layer 34 in the photoelectric conversion elements 40 in this embodiment is made of, for example, GIGS, and can be manufactured by a known method of manufacturing GIGS solar cells.

The separation grooves (P1) 33 of the back electrodes 32, the grooves (P2) 37 reaching the back electrodes 32, and the opening grooves (P3) 39 reaching the back electrodes 32 may be formed by laser scribing or mechanical scribing.

In the thin-film solar cell 30, light entering the photoelectric conversion elements 40 from the side of the transparent electrode 38 passes through the transparent electrode 38 and the buffer layers 36 and causes the photoelectric conversion layers 34 to generate electromotive force, thus producing a current that flows, for example, from the transparent electrode 38 to the back electrodes 32. Note that the arrows shown in FIG. 1 indicate the directions of the current, and the direction in which electrons move is opposite to that of current. Therefore, in the photoelectric converters 48, the leftmost back electrode 32 in FIG. 1 has a positive polarity (plus polarity) and the rightmost back electrode 32 has a negative polarity (minus polarity).

In this embodiment, electric power generated in the thin-film solar cell 30 can be output from the thin-film solar cell 30 through the first conductive member 42 and the second conductive member 44.

Also, in this embodiment, the first conductive member 42 has a negative polarity, and the second conductive member 44 has a positive polarity. The polarities of the first conductive member 42 and the second conductive member 44 may be reversed; their polarities may vary according to the configuration of the photoelectric conversion elements 40, the configuration of the thin-film solar cell 30, etc.

In this embodiment, the photoelectric conversion elements 40 are formed so as to be connected in series in the longitudinal direction L of the substrate 10 through the back electrodes 32 and the transparent electrode 38, but the present invention is not limited thereto. For example, the photoelectric conversion elements 40 may be formed so as to be connected in series in the width direction through the back electrodes 32 and the transparent electrode 38.

The back electrodes 32 and the transparent electrode 38 of the photoelectric conversion elements 40 are both provided to collect current generated by the photoelectric conversion layers 34. Both the back electrodes 32 and the transparent electrode 38 is each made of a conductive material. The transparent electrode 38 must be have translucency.

The back electrodes 32 are formed, for example, of molybdenum (Mo), chromium (Cr) or tungsten (W), or a combination thereof. The back electrodes 32 may have a single-layer structure or a laminated structure such as a two-layer structure. The back electrodes 32 are preferably made of molybdenum (Mo).

The back electrodes 32 may be formed by any vapor-phase film deposition method such as electron beam vapor deposition or sputtering.

The back electrodes 32 generally have a thickness of about 800 nm, preferably 200 nm to 600 nm, and more preferably 200 nm to 400 nm. By making the thickness of the back electrodes 32 thinner than standard, it is possible to increase the diffusion speed of the alkali metal from the alkali supply layer 50 to the photoelectric conversion layers 34, as will be described later. Moreover, with this arrangement, the material costs of the back electrodes 32 can be reduced, and the formation speed of the back electrodes 32 can be increased.

The transparent electrode 38 is formed, for example, of ZnO doped with Al, B, Ga, Sb etc., ITO (indium tin oxide), SnO₂, or a combination thereof. The transparent electrode 38 may have a single-layer structure or a laminated structure such as a two-layer structure. The thickness of the transparent electrode 38, which is not specifically limited, is preferably 0.3-1 μm.

The method of forming the transparent electrode 38 is not particularly limited; they may be formed by coating techniques or vapor-phase deposition techniques such as electron beam vapor deposition and sputtering.

The buffer layers 36 are provided to protect the photoelectric conversion layers 34 when forming the transparent electrode 38 and to allow the light impinging on the transparent electrode 38 to enter the photoelectric conversion layers 34.

The buffer layers 36 are made of, for example, CdS, ZnS, ZnO, ZnMgO, or ZnS (O, OH), or a combination thereof.

The buffer layers 36 preferably have a thickness of 30 nm to 100 nm. The buffer layers 36 are formed by, for example, chemical bath deposition (CBD) method.

The photoelectric conversion layer 34 has a photoelectric conversion function, such that it generates current by absorbing light that has reached it through the transparent electrode 38 and the buffer layer 36. According to the embodiment under consideration, the photoelectric conversion layers 34 are not particularly limited in structure; the photoelectric conversion layers 34 are made of, for example, at least one compound semiconductor of a chalcopyrite structure. The photoelectric conversion layers 34 may be made of at least one kind of compound semiconductor composed of a group Ib element, a group IIIb element, and a group VIb element.

For high optical absorbance and high photoelectric conversion efficiency, the photoelectric conversion layers 34 are preferably formed of at least one kind of compound semiconductor composed of at least one kind of group Ib element selected from the group consisting of Cu and Ag, at least one kind of group IIIb element selected from the group consisting of Al, Ga, and In, and at least one kind of group VIb element selected from the group consisting of S, Se, and Te. Examples of the compound semiconductor include CuAlS₂, CuGaS₂, CuInS₂ CuAlSe₂, CuGaSe₂, CuInSe₂ (CIS), AgAlS₂, AgGaS₂, AgInS₂, AgAlSe₂, AgGaSe₂, AgInSe₂, AgAlTe₂, AgGaTe₂, AgInTe₂, Cu(In₁₋ₓGaₓ)Se₂ (CIGS), Cu(In₁₋ₓAlₓ)Se₂, Cu(In₁₋ₓGaₓ) (S, Se)₂, Ag(In₁₋ₓGaₓ)Se₂ and Ag(In₁₋ₓGaₓ) (S, Se)₂.

The photoelectric conversion layers 34 especially preferably contain CuInSe₂(CIS) and/or Cu(In, Ga)Se₂ (CIGS), which is obtained by solid-dissolving (solute) Ga in the former. CIS and CIGS are semiconductors each having a chalcopyrite crystal structure, which reportedly have high optical absorbance and high photoelectric conversion efficiency. Further, they have little deterioration of efficiency under exposure to light, and exhibit excellent durability.

The photoelectric conversion layer 34 contains impurities for obtaining the desired semiconductor conductivity type. Impurities may be added to the photoelectric conversion layer 34 by diffusion from adjacent layers and/or direct doping into the photoelectric conversion layer 34. There may be a concentration distribution of constituent elements of group semiconductors and/or impurities in the photoelectric conversion layer 34, which may contain a plurality of layer regions formed of materials having different semiconductor properties such as n-type, p-type, and i-type.

For example, in a CIGS semiconductor, when provided with a distribution in the amount of Ga in the direction of thickness in the photoelectric conversion layer 34, the band gap width, carrier mobility, etc. can be controlled, and thus high photoelectric conversion efficiency is achieved.

The photoelectric conversion layers 34 may contain one or two or more kinds of semiconductors other than group I-III-VI semiconductors. Example of semiconductors other than group I-III-VI semiconductors include a semiconductor formed of a group IVb element such as Si (group IV semiconductor), a semiconductor formed of a group IIIb element and a group Vb element (group III-V semiconductor) such as GaAs, and a semiconductor formed of a group IIb element and a group VIb (group II-V1 semiconductor) such as CdTe. The photoelectric conversion layers 34 may contain any other component than a semiconductor and impurities used to obtain a desired conductivity type, provided that no detrimental effects are thereby produced on the properties.

The photoelectric conversion layers 34 may contain a group I-III-V1 semiconductor in any amount as deemed appropriate. The ratio of group I-III-V1 semiconductor contained in the photoelectric conversion layers 34 is preferably 75 mass % or more and, more preferably, 95 mass % or more and, most preferably, 99 mass % or more.

Note that when the photoelectric conversion layers 34 in this embodiment are made of compound semiconductors formed of a group Ib element, a group IIIb element, and a group VIb element, the metal base 12 is preferably formed of carbon steel or ferrite stainless steel, and the back electrodes 32 are preferably made of molybdenum.

Exemplary known methods of forming the CIGS layer include 1) multi-source simultaneous evaporation, 2) selenization, 3) sputtering, 4) hybrid sputtering, and 5) mechanochemical processing.

1) Known multi-source co-evaporation methods include: the three-stage method (J. R. Tuttle et al., Mat. Res. Soc. Symp. Proc., Vol. 426 (1966), p. 143, etc.), and the co-evaporation method of the EC group (L. Stolt et al.: Proc. 13th ECPVSEC (1995, Nice), 1451, etc.).

According to the former three-phase method, firstly, In, Ga, and Se are simultaneously vapor-deposited under high vacuum at a substrate temperature of 300° C., which is then increased to 500° C. to 560° C. to simultaneously vapor-deposit Cu and Se, whereupon In, Ga and Se are further simultaneously evaporated. The latter simultaneous evaporation method by EC group is a method which involves evaporating copper-excess CIGS in the earlier stage of evaporation, and evaporating indium-excess CIGS in the latter half of the stage.

Improvements have been made on the foregoing methods to improve the crystallinity of CIGS films, and the following methods are known:

a) Method using ionized Ga (H. Miyazaki et al., Phys. Stat. Sol. (a), Vol. 203 (2006), p. 2603, etc.);
b) Method using cracked Se (a pre-printed collection of speeches given at the 68th Academic Lecture by the Japan Society of Applied Physics) (autumn, 2007, Hokkaido Institute of Technology), 7β-L-6, etc.);
c) Method using radicalized Se (a pre-printed collection of speeches given at the 54th Academic Lecture by the Japan Society of Applied Physics) (spring, 2007, Aoyama Gakuin Univ.), 29P-ZW-10, etc.); and
d) Method using a light excitation process (a pre-printed collection of speeches given at the 54th Academic Lecture by the Japan Society of Applied Physics) (spring, 2007, Aoyama Gakuin Univ.), 29P-ZW-14, etc.).

2) The selenization method is also called a two-stage method, whereby firstly a metal precursor formed of a laminated film such as a Cu layer/In layer, a (Cu—Ga) layer/In layer, or the like is formed by sputter deposition, vapor deposition, or electrodeposition, and the film thus formed is heated in selenium vapor or hydrogen selenide to a temperature of 450° C. to 550° C. to produce a selenide such as Cu(In₁₋ₓGaₓ)Se₂ by thermal diffusion reaction. This method is called vapor-phase selenization. Another exemplary method is solid-phase selenization in which solid-phase selenium is deposited on a metal precursor film and selenized by a solid-phase diffusion reaction using the solid-phase selenium as the selenium source.

In order to avoid abrupt volume expansion that may take place during the selenization, selenization is implemented by known methods including a method in which selenium is previously mixed into the metal precursor film at a given ratio (T. Nakada et al., Solar Energy Materials and Solar Cells 35 (1994), 204-214, etc.); and a method in which selenium is sandwiched between thin metal films (e.g., as in Cu layer/In layer/Se layer Cu layer/In layer/Se layer) to form a multiple-layer precursor film (T. Nakada et al., Proc. of 10th European Photovoltaic Solar Energy Conference (1991), 887-890, etc.).

An exemplary method of forming a graded band gap CIGS film is a method which involves first depositing a Cu—Ga alloy film, depositing an In film thereon, and selenizing, while making a Ga concentration gradient in the film thickness direction using natural thermal diffusion (K. Kushiya et al., Tech. Digest 9th Photovoltaic Science and Engineering Conf. Miyazaki, 1996 (Intn. PVSEC-9, Tokyo, 1996), p. 149, etc.).

3) Known sputter deposition methods include:

a technique using CuInSe₂ polycrystal as a target, one called two-source sputtering using H₂Se/Ar mixed gas as sputter gas with Cu₂Se and In₂Se₃ as targets (J. H. Ermer et al., Proc. 18th IEEE Photovoltaic Specialists Conf. (1985), 1655-1658, etc.) and

a technique called three-source sputtering whereby a Cu target, an In target, and an Se or CuSe target are sputtered in Ar gas (T. Nakada et al., Jpn. J. Appl. Phys., 32 (1993), L1169-L1172, etc.).

4) Exemplary known methods for hybrid sputtering include one in which Cu and In metals are subjected to DC sputtering, while only Se is vapor-deposited in the aforementioned sputter deposition method (T. Nakada et al., Jpn. Appl. Phys., 34 (1995), 4715-4721, etc.).

5) An exemplary method for mechanochemical processing includes one in which a material selected according to the GIGS composition is placed in a planetary ball mill container and mixed by mechanical energy to obtain pulverized CIGS, which is then applied to a substrate by screen printing and annealed to obtain a CIGS film (T. Wada et al., Phys. Stat. Sol. (a), Vol. 203 (2006), p. 2593, etc.).

Other exemplary methods for forming CIGS films include screen printing, close-spaced sublimation, MOCVD and spraying (wet deposition). For example, crystals with a desired composition can be obtained by a method which involves forming a fine particle film containing a group Ib element, a group IIIb element and a group VIb element on a substrate by, for example, screen printing (wet deposition) or spraying (wet deposition) and subjecting the fine particle film to pyrolysis treatment (which may be a pyrolysis treatment carried out under a group VIb element atmosphere) (JP 9-74065 A, JP 9-74213 A, etc.).

In this embodiment, the difference between the coefficients of linear thermal expansion of the metal base 12 and the photoelectric conversion layer 34 is preferably less than 3×10⁻⁶/° C.

Of the main compound semiconductors for use in the photoelectric conversion layer 34, GaAs as a typical group III-V compound semiconductor has a linear expansion coefficient of 5.8×10⁻⁶/° C., CdTe as a typical group II-VI compound semiconductor has a linear expansion coefficient of 4.5×10⁻⁶/° C., and Cu(InGa)Se₂ as a typical group I-III-V1 compound semiconductor has a linear expansion coefficient of 10×10⁻⁶/° C.

A large thermal expansion difference between the metal base 12 and the photoelectric conversion layer 34 may cause a film deposition defect such as delamination upon cooling of the compound semiconductor deposited on the substrate 10 at a high temperature of at least 500° C. for the photoelectric conversion layer 34. A large internal stress within the compound semiconductor due to the difference in the thermal expansion from the metal base 12 may lower the photoelectric conversion efficiency of the photoelectric conversion layer 34. A difference in the coefficient of linear expansion between the metal base 12 and the photoelectric conversion layer 34 (compound semiconductor) of less than 3×10⁻⁶/° C. does not readily cause delamination or other film deposition defects, and is therefore preferred. More preferably, the difference in the coefficient of linear expansion is less than 1×10⁻⁶/° C. The thermal expansion coefficient and the difference in the thermal expansion coefficient are obtained at room temperature (23° C.)

The alkali supply layer 50 diffuses the alkali metal element (alkali ion), such as Na (Na⁺) for example, into the photoelectric conversion layers 34 (CICS layers), thereby supplying alkali metal, for example, during formation of the photoelectric conversion layers 34. The alkali supply layer 50 is made from an electrically conductive material.

Note that the alkali supply layer 50 may have a single-layer structure, or may have a multiple-layer structure in which layers of different compositions are laminated, provided that it is electrically conductive.

Exemplary alkali metals include Li, Na, K, Rb, and Cs. Exemplary alkali-earth metals include Be, Mg, Ca, Sr, and Ba. For reasons such as ease of achieving a chemically safe and easy-to handle compound, ease of discharge from the alkali supply layer 50 by heat, and a high crystallinity improvement effect of the photoelectric conversion layers 34, the alkali metal is preferably at least one kind selected from Na, K, Rb, and Cs, more preferably Na and/or K, and especially preferably Na.

In this embodiment, the alkali supply layer 50 is preferably made of Mo that contains Na and/or an Na compound as the alkali metal. That is, the alkali supply layer 50 is preferably made of Mo that contains Na and/or an Na compound. In this case, the alkali supply layer 50 contains an Na compound such as NaF, sodium molybdate (Na₂MoO₄) or the like and a sodium polyacid or the like.

If the alkali supply layer 50 is made of Mo containing Na and/or an Na compound, DC sputtering, for example, can be used. For this reason, the deposition rate can be increased compared to the case where the alkali supply layer 50 is made of an insulator. As a result, mass producibility of the photoelectric conversion element 40, and consequently the thin-film solar cell 30, can be improved.

Note that the alkali metal content (concentration) by Na conversion in the alkali supply layer 50 is preferably 3-15 at. %, and more preferably 5-10 at. %. If the content of the alkali metal by Na conversion is 3 at. % to 15 at. %, the composition of the Mo containing Na is not particularly limited and includes, for example, one or more than one type of alkali metal and/or alkali-earth metal.

In this embodiment, the alkali metal content (concentration) may be the content upon formation of the alkali supply layer 50, or the content upon formation of the photoelectric conversion element 40.

When the content of the alkali metal in the alkali supply layer 50 is less than 3 at. % by Na conversion, the level of improvement of conversion efficiency is low, even when the alkali metal is diffused into the photoelectric conversion layer 34.

On the other hand, if the alkali metal content by Na conversion in the alkali supply layer 50 exceeds 15 at. %, problems occur in cases where the alkali supply layer 50 is to be formed using DC sputtering, in that it is difficult to homogeneously disperse the alkali metal in the target and the alkali metal precipitates out in the target, and it is difficult to produce the target. Additionally, the alkali supply layer 50 of good film quality cannot be obtained.

Additionally, since a thick alkali supply layer 50 makes the layers more susceptible to delamination, the alkali supply layer 50 preferably has a thickness of 100 nm to 800 nm, more preferably 100 nm to 400 nm.

In this embodiment, since the alkali metal content (concentration) of the alkali supply layer 50 is sufficiently high, enough alkali metal can be supplied to the photoelectric conversion layer 34 to improve conversion efficiency even when the thickness of the alkali supply layer 50 is 100-800 nm.

The diffusion prevention layer 52 prevents the alkali metal contained in the alkali supply layer 50 from diffusing to the substrate 10, and increases the amount of alkali metal diffused to the photoelectric conversion layers 34.

The diffusion prevention layer 52 can be made of a nitride, for example, and is preferably an insulator.

Specifically, the nitride that makes up the diffusion prevention layer 52 may be TiN (9.4×10⁻⁶/° C.), ZrN (7.2×10⁻⁶/° C.), BN (6.4×10⁻⁶/° C.), or AlN (5.7×10⁻⁶/° C.). Of these, the diffusion prevention layer 52 is preferably a material having a small difference in thermal expansion coefficient from that of the insulation layer 16 or aluminum anodized film of the substrate 10, and is thus preferably made of ZrN, BN, or AlN. Among these, the insulator is preferably BN or AlN, and these are preferred for the diffusion prevention layer 52. Further, AlN is most preferred due to its having the smallest difference in the thermal expansion coefficient from that of the aluminum anodized film.

Thus, it is possible to uniform the thermal expansion coefficients of the diffusion prevention layer 52, the substrate 10, and the photoelectric conversion layers 34 and, in turn, maintain and improve the adhesion of the diffusion prevention layer 52, the substrate 10, and the photoelectric conversion layers 34, and prevent delamination of the substrate 10 and the photoelectric conversion layers 34.

Further, the diffusion prevention layer 52 may be made of an oxide. In this case, the oxide may be TiO₂ (9.0×10⁻⁶/° C.), ZrO₂ (7.6×10⁻⁶/° C.), HfO₂ (6.5×10⁻⁶/° C.), or Al₂O₃ (8.4×10⁻⁶/° C.). If the diffusion prevention layer 52 is made of an oxide, it is preferably also an insulator.

Here, it is believed that while the oxide film prevents diffusion of Na into the substrate 10 by containing Na therein, the nitride film does not readily contain an alkali metal such as Na within the film, and thus inhibits diffusion into the nitride film, thereby promoting Na diffusion to the upper CIGS layer more than the alkali supply layer. For this reason, there is the effect that alkali metal is diffused into the photoelectric conversion layer 34 (CIGS layer) more when the diffusion prevention layer 52 is made of a nitride than when it is made of an oxide. For this reason, the diffusion prevention layer made of a nitride is preferred.

The diffusion prevention layer 52 is preferably thick since increased thickness enhances its function of preventing diffusion into the substrate 10 and its function of increasing the amount of alkali metal diffused into the photoelectric conversion layers 34. Nevertheless, since a greater thickness causes the diffusion prevention layer 52 to become the origin of delamination, the diffusion prevention layer 52 preferably has a thickness of 10 nm to 200 nm, and more preferably 10 nm to 100 nm.

As described above, in the case where the diffusion prevention layer 52 is made of an insulator, the electrical insulation properties (withstand voltage characteristics) and heat resistance of the substrate 10 are further improved in addition to the insulation layer 16 of the substrate 10, making it possible to achieve a photoelectric conversion element 40 and solar cell 30 having high withstand voltage characteristics.

Next, the manufacturing method of the thin-film solar cell 30 of the embodiment under consideration will be described.

First, substrate 10 formed as described above is prepared.

Next, a TiN film, ZrN film, BN film, or AlN film serving as the diffusion prevention layer 52 is formed by, for example, sputtering on the surface 16a of the insulation layer 16 of the substrate 10 using a film deposition apparatus.

Then, an Mo film containing Na and/or an Na compound, serving as the alkali supply layer 50, is formed, for example, by DC sputtering on the surface 52a of the diffusion prevention layer 52 using a film deposition apparatus.

Then, a molybdenum film serving as the back electrodes 32 is formed by, for example, sputtering on the surface 50a of the alkali supply layer 50 using a film deposition apparatus.

Then, for example, laser scribing is used to scribe the molybdenum film at a first predetermined position to form the separation grooves (P1) 33 extending in the width direction of the substrate 10. The back electrodes 32 separated from each other by the separation grooves (P1) 33 are thus formed.

Then, for example, a CIGS layer, which serves as a photoelectric conversion layer 34 (p-type semiconductor layer), is formed by any of the film deposition methods described above using a film deposition apparatus, so as to cover the back electrodes 32 and fill in the separation grooves (P1) 33.

Then, a CdS layer (n-type semiconductor layer) serving as the buffer layer 36 is formed on the CIGS layer by, for example, chemical bath deposition (CBD) method. A p-n junction semiconductor layer is thus formed.

Then, laser scribing is used to scribe the second position, which differs from the first position of the separation grooves (P1) 33, so as to form grooves (P2) 37 extending in the width direction of the substrate 10 and reach the back electrodes 32.

Then, a layer of ZnO doped with, for example, aluminum, boron, gallium, antimony or the like, which serves as the transparent electrode 38 is formed on the buffer layer 36 by sputtering or coating using a film deposition apparatus so as to fill the grooves (P2) 37.

Then, laser scribing is used to scribe a third position, which differs from the first position of the separation grooves (P1) 33 and the second position of the grooves (P2) 37, so as to form opening grooves (P3) 39 which extend in the width direction of the substrate 10 and reach the back electrodes 32. Thus, a plurality of the power generating cells 54 are formed on the laminated body of the substrate 10, the diffusion prevention layer 52, and the alkali supply layer 50 to form the power generating layer 56.

Then, the photoelectric conversion elements 40 formed on the rightmost and leftmost back electrodes 32 in the longitudinal direction L of the substrate 10 are removed by, for example, laser scribing or mechanical scribing, to expose the back electrodes 32. Then, the first conductive member 42 and the second conductive member 44 are connected by, for example, ultrasonic soldering onto the rightmost and leftmost back electrodes 32, respectively.

The thin-film solar cell 30 in which the plurality of photoelectric conversion elements 40 are connected in series can be thus manufactured as shown in FIG. 1.

If necessary, a bond/seal layer (not shown), a water vapor barrier layer (not shown), and a surface protection layer (not shown) are arranged on the front side of the resulting thin-film solar cell 30, and a bond/seal layer (not shown) and a back sheet (not shown) are formed on the back side of the thin-film solar cell 30, that is, on the back side of the substrate 10, and these layers are integrated by vacuum lamination, for example. A thin-film solar cell module is thus obtained.

In this embodiment, the alkali supply layer 50 is provided, making it possible to control the quantity of alkali metal supplied to the photoelectric conversion layer 34 (GIGS layer) precisely and with good reproducibility. The conversion efficiency of the photoelectric conversion elements 40 can be thus heightened and the photoelectric conversion elements 40 can be thus manufactured at a high yield.

Further, the provision of the diffusion prevention layer 52 makes it possible to obtain a photoelectric conversion element 40 having better conversion efficiency, because the amount of diffusion of alkali metal into the photoelectric conversion layer 34 can be increased.

Further, the provision of the diffusion prevention layer 52 makes it possible to achieve a favorable conversion efficiency even if the alkali supply layer 50 is thin. In this embodiment, since the alkali supply layer 50 can be made thin, it is possible to shorten the fabrication time of the alkali supply layer 50 and improve the producibility of the photoelectric conversion element 40 and the thin-film solar cell 30. This also makes it possible to keep the alkali supply layer 50 from becoming the origin of delamination.

Further, in this embodiment, the substrate 10 serves as the substrate with an insulation layer comprising the metallic substrate 15, wherein the metal base 12 and the Al base 14 are laminated and unified, and the insulation layer 16 that is formed on the surface 14a of the Al base 14 of the metallic substrate 15, making it possible to maintain high insulation properties and high strength as well as suppressing generation of strain even when subjected to a film deposition process at a temperature of 500° C. or higher, for example, thereby enabling manufacturing at a high temperature of 500° C. or higher. As a result, a compound semiconductor can be formed as the photoelectric conversion layer at 500° C. or higher. The compound semiconductor constituting the photoelectric conversion layer can improve the photoelectric conversion characteristics when formed at higher temperatures, and thus, in this way as well, it is possible to manufacture the photoelectric conversion element 40 having the photoelectric conversion layer 34 with improved photoelectric conversion characteristics.

Moreover, since the manufacturing process can be performed at a high temperature of 500° C. or higher, it is possible to eliminate restrictions on handling and the like during manufacturing.

As a result, the substrate 10 is imparted with excellent heat resistance, making it possible to achieve a thin-film solar cell 30 with excellent durability and an excellent storage life. For this reason, the thin-film solar cell module also has excellent durability and storage life.

Furthermore, in this embodiment, the insulation layer 16 is formed and the diffusion prevention layer 52 is made of an insulator, making it possible to further improve the electrical insulation properties (withstand voltage characteristics) of the substrate 10. Moreover, as described above, the substrate 10 exhibits excellent heat resistance. The thin-film solar cell 30 can thus exhibit even better durability and an even better storage life. This makes it possible to achieve a thin-film solar cell sub-module and solar cell module that exhibit even better durability and an even better storage life as well.

Also, in this embodiment, the substrate 10 is produced by the roll-to-roll process and is flexible. This makes it possible to manufacture the photoelectric conversion element 40 and the thin-film solar cell 30 while transporting the substrate 10 in the longitudinal direction L using a roll-to-roll process as well. With the thin-film solar cell 30 thus manufactured using an inexpensive roll-to-roll process, the cost of manufacturing the thin-film solar cell 30 can be reduced. This makes it possible to reduce the cost of the solar cell sub-module and thin-film solar cell module.

The present invention is basically as described above. While the photoelectric conversion element, thin-film solar cell, and photoelectric conversion element manufacturing method have been described above in detail, the present invention is by no means limited to the above embodiments, and various improvements or design modifications may be made without departing from the scope and spirit of the present invention.

### Example 1

The following specifically describes working examples of the photoelectric conversion element of the present invention.

In this example 1, working examples 1 to 10 and comparison example 1 described below are manufactured, and the respective alkali metal content of the respective photoelectric conversion layers and the respective conversion efficiency of the photoelectric conversion elements are examined.

### Working Example 1

A metallic substrate was obtained by pressure-bonding by cold rolling the commercial ferrite stainless steel material (material grade SUS430) and the aluminum material (hereinafter Al material) having a high aluminum purity of 4N, and decreasing the thickness thereof to form a 3-layered clad material having a ferrite stainless steel thickness of 50 μm and an Al material thickness of 30 μm. The structure of this metallic substrate consisted of Al material (30 μm)/ferrite stainless steel material (50 μm)/Al material (30 μm).

The stainless steel surface and end surface of this metallic substrate was then covered by a masking film. Subsequently, the metallic substrate was ultrasonically cleaned in an ethanol solution, and electrolytic polishing with an acetic acid+perchloric acid solution, and 40 V potentiostatic electrolysis in an 80 g/L oxalic acid solution to form an anodized film serving as the insulation layer, having a thickness of 10 μm, on the surface of the Al material. The thickness of the Al material after anodization treatment was 15 μm. As a result of the above process, the substrate with an insulation layer having the structure of an anodized film (10 μm)/Al material (15 μm)/ferrite stainless steel (50 μm)/Al material (15 μm)/anodized film (10 μm) was achieved.

Next, a film of aluminum nitride (AlN), serving as the diffusion prevention layer, was formed by reactive sputtering to a thickness of 100 nm on one side of the substrate with an insulation layer.

Then, Mo containing Na₂MoO₄ (Na compound), serving as an alkali supply layer (Na supply source), was formed by DC sputtering to a thickness of 400 nm on the diffusion prevention layer, and an Mo—Na film was obtained. The content of the alkali metal (Na concentration) in this Mo—Na film was 7 at. % by Na conversion.

The alkali supply layer was formed under the film deposition conditions of target size (diameter) of 8 inches, power density of 7 W/cm², and deposition pressure of 0.5 Pa (in argon atmosphere) using a DC pulse power source. In this case, the film deposition rate was 300 nm/minute.

A film of Mo, serving as the back electrodes, was formed by DC sputtering to a thickness of 800 nm on the alkali supply layer.

Then, a film of Cu(In_{0.7}Ga_{0.3})Se₂, serving as the photoelectric conversion layer (semiconductor layer), was deposited on the back electrodes with the substrate temperature at 550° C.

The Cu(In_{0.7}Ga_{0.3})Se₂ film was formed to a thickness of 2 μm using K-Cells (Knudsen cells) as the vapor deposition source.

Then, the CdS buffer layer was formed on the surface of the photoelectric conversion layer (GIGS layer) to a thickness of 50 nm by CBD method (chemical deposition method). Next, a ZnO layer was formed by sputtering to a thickness of 50 nm on the surface of the CdS buffer layer. Further, an Al—ZnO layer serving as the transparent electrode layer was formed by sputtering to a thickness of 300 nm. Finally, on the surface of the Al—ZnO layer, an aluminum layer serving as collection electrodes was formed by vapor deposition. This was used as working example 1.

### Working Example 2

A film of titanium nitride (TiN), serving as the diffusion prevention layer, was formed by reactive sputtering to a thickness of 100 nm on one side of the substrate with an insulation layer using the same substrate with an insulation layer as in working example 1.

Then, Mo containing Na₂MoO₄, serving as an alkali supply layer (Na supply source), was formed by DC sputtering to a thickness of 400 nm on the diffusion prevention layer under the same film deposition conditions of working example 1, and an Mo—Na film was obtained. The content of the alkali metal (Na concentration) in this Mo—Na film was 7 at. % by Na conversion.

Then, a film of Mo, serving as the back electrodes, was formed by DC sputtering to a thickness of 800 nm on the alkali supply layer. On the back electrodes, the photoelectric conversion layer (CIGS layer), the CdS buffer layer, the ZnO layer, the Al—ZnO layer and the collection electrodes were formed in that order in the same way as in working example 1 above. This was used as working example 2.

### Working Example 3

A film of zirconium nitride (ZrN), serving as the diffusion prevention layer, was formed by reactive sputtering to a thickness of 100 nm on one side of the substrate with an insulation layer using the same substrate with an insulation layer as in working example 1.

Then, Mo containing Na₂MoO₄, serving as an alkali supply layer (Na supply source), was formed by DC sputtering to a thickness of 400 nm on the diffusion prevention layer under the same film deposition conditions of working example 1, and an Mo—Na film was obtained. The content of the alkali metal (Na concentration) in this Mo—Na film was 7 at. % by Na conversion.

Then, a film of Mo, serving as the back electrodes, was formed by DC sputtering to a thickness of 800 nm on the alkali supply layer. On the back electrodes, the photoelectric conversion layer (CIGS layer), the CdS buffer layer, the ZnO layer, the Al—ZnO layer and the collection electrodes were formed in that order in the same way as in working example 1 above. This was used as working example 3.

### Working Example 4

A film of aluminum nitride (AlN), serving as the diffusion prevention layer, was formed by reactive sputtering to a thickness of 100 nm on one side of the substrate with an insulation layer using the same substrate with an insulation layer as in working example 1.

Then, Mo containing Na₂MoO₄, serving as an alkali supply layer (Na supply source), was formed by DC sputtering to a thickness of 200 nm on the diffusion prevention layer under the same film deposition conditions of working example 1, and an Mo—Na film was obtained. The content of the alkali metal (Na concentration) in this Mo—Na film was 7 at. % by Na conversion.

Then, a film of Mo, serving as the back electrodes, was formed by DC sputtering to a thickness of 800 nm on the alkali supply layer. On the back electrodes, the photoelectric conversion layer (CIGS layer), the CdS buffer layer, the ZnO layer, the Al—ZnO layer and the collection electrodes were formed in that order in the same way as in working example 1 above. This was used as working example 4.

### Working Example 5

A film of aluminum nitride (AlN), serving as the diffusion prevention layer, was formed by reactive sputtering to a thickness of 100 nm on one side of the substrate with an insulation layer using the same substrate with an insulation layer as in working example 1.

Then, Mo containing Na₂MoO₄, serving as an alkali supply layer (Na supply source), was formed by DC sputtering to a thickness of 800 nm on the diffusion prevention layer under the same film deposition conditions of working example 1, and an Mo—Na film was obtained. The content of the alkali metal (Na concentration) in this Mo—Na film was 7 at. % by Na conversion.

Then, a film of Mo, serving as the back electrodes, was formed by DC sputtering to a thickness of 800 nm on the alkali supply layer. On the back electrodes, the photoelectric conversion layer (CIGS layer), the CdS buffer layer, the ZnO layer, the Al—ZnO layer and the collection electrodes were formed in that order in the same way as in working example 1 above. This was used as working example 5.

### Working Example 6

A film of aluminum nitride (AlN), serving as the diffusion prevention layer, was formed by reactive sputtering to a thickness of 100 nm on one side of the substrate with an insulation layer using the same substrate with an insulation layer as in working example 1.

Then, Mo containing Na₂MoO₄, serving as an alkali supply layer (Na supply source), was formed by DC sputtering to a thickness of 200 nm on the diffusion prevention layer under the same film deposition conditions of working example 1, and an Mo—Na film was obtained. The content of the alkali metal (Na concentration) in this Mo—Na film was 7 at. % by Na conversion.

Then, a film of Mo, serving as the back electrodes, was formed by DC sputtering to a thickness of 400 nm on the alkali supply layer. On the back electrodes, the photoelectric conversion layer (CIGS layer), the CdS buffer layer, the ZnO layer, the Al—ZnO layer and the collection electrodes were formed in that order in the same way as in working example 1 above. This was used as working example 6.

### Working Example 7

A film of aluminum nitride (AlN), serving as the diffusion prevention layer, was formed by reactive sputtering to a thickness of 100 nm on one side of the substrate with an insulation layer using the same substrate with an insulation layer as in working example 1.

Then, Mo containing Na₂MoO₄, serving as an alkali supply layer (Na supply source), was formed by DC sputtering to a thickness of 400 nm on the diffusion prevention layer under the same film deposition conditions of working example 1, and an Mo—Na film was obtained. The content of the alkali metal (Na concentration) in this Mo—Na film was 7 at. % by Na conversion.

Then, a film of Mo, serving as the back electrodes, was formed by DC sputtering to a thickness of 400 nm on the alkali supply layer. On the back electrodes, the photoelectric conversion layer (CIGS layer), the CdS buffer layer, the ZnO layer, the Al—ZnO layer and the collection electrodes were formed in that order in the same way as in working example 1 above. This was used as working example 7.

### Working Example 8

A film of titanium oxide (TiO₂), serving as the diffusion prevention layer, was formed by reactive sputtering to a thickness of 100 nm on one side of the substrate with an insulation layer using the same substrate with an insulation layer as in working example 1.

Then, Mo containing Na₂MoO₄, serving as an alkali supply layer (Na supply source), was formed by DC sputtering to a thickness of 400 nm on the diffusion prevention layer under the same film deposition conditions of working example 1, and an Mo—Na film was obtained. The content of the alkali metal (Na concentration) in this Mo—Na film was 7 at. % by Na conversion.

Then, a film of Mo, serving as the back electrodes, was formed by DC sputtering to a thickness of 800 nm on the alkali supply layer. On the back electrodes, the photoelectric conversion layer (CIGS layer), the CdS buffer layer, the ZnO layer, the Al—ZnO layer and the collection electrodes were formed in that order in the same way as in working example 1 above. This was used as working example 8.

### Working Example 9

A film of alumina (Al₂O₃), serving as the diffusion prevention layer, was formed by reactive sputtering to a thickness of 100 nm on one side of the substrate with an insulation layer using the same substrate with an insulation layer as in working example 1.

Then, Mo containing Na₂MoO₄, serving as an alkali supply layer (Na supply source), was formed by DC sputtering to a thickness of 400 nm on the diffusion prevention layer under the same film deposition conditions of working example 1, and an Mo—Na film was obtained. The content of the alkali metal (Na concentration) in this Mo—Na film was 7 at. % by Na conversion.

Then, a film of Mo, serving as the back electrodes, was formed by DC sputtering to a thickness of 800 nm on the alkali supply layer. On the back electrodes, the photoelectric conversion layer (CIGS layer), the CdS buffer layer, the ZnO layer, the Al—ZnO layer and the collection electrodes were formed in that order in the same way as in working example 1 above. This was used as working example 9.

### Working Example 10

A film of aluminum nitride (AlN), serving as the diffusion prevention layer, was formed by reactive sputtering to a thickness of 100 nm on one side of the substrate with an insulation layer using the same metal substrate with an insulation layer as in working example 1.

Then, Mo containing Na₇MoO₄, serving as an alkali supply layer (Na supply source), was formed by DC sputtering to a thickness of 400 nm on the diffusion prevention layer under the same film deposition conditions of working example 1, and an Mo—Na film was obtained. The content of the alkali metal (Na concentration) in this Mo—Na film was 7 at. % by Na conversion.

Then, a film of Mo, serving as the back electrode, was formed by DC sputtering to a thickness of 200 nm on the alkali supply layer. On the back electrode, the photoelectric conversion layer (CIGS layer), the CdS buffer layer, the ZnO layer, the Al—ZnO layer and the collection electrode were formed in that order in the same way as in working example 1 above. This was used as working example 10.

### Comparison Example 1

Using the same metal substrate with an insulation layer as in working example 1, without forming a diffusion prevention layer, Mo containing Na₂MoO₄, serving as an alkali supply layer (Na supply source), was formed by DC sputtering to a thickness of 400 nm on one surface of the metal substrate with an insulation layer, and an Mo—Na film was obtained. The content of the alkali metal (Na concentration) in this Mo—Na film was 7 at. % by Na conversion.

Then, a film of Mo, serving as the back electrodes, was formed by DC sputtering to a thickness of 800 nm on the alkali supply layer. On the back electrodes, the photoelectric conversion layer (CIGS layer), the CdS buffer layer, the ZnO layer, the Al—ZnO layer and the collection electrodes were formed in that order in the same way as in working example 1 above. This was used as comparison example 1.

The presence of a diffusion prevention layer, the structure of the diffusion prevention layer, the structure of the alkali supply layer and the structure of the back electrodes of the photoelectric conversion elements of working examples 1 to 10 and comparison example 1 are shown in Table 1.

In this example 1, the Na concentration (alkali metal content) of the photoelectric conversion layer (CIGS layer) of each of the photoelectric conversion elements of working examples 1 to 10 and comparison example 1 was measured.

This Na concentration was measured using SIMS (secondary ion mass spectrometry) given O₂⁺ as the primary ion type and 6.0 kV as the acceleration voltage for measurement. Although the Na concentration within the photoelectric conversion layer (CIGS layer) was distributed in the thickness direction, the mean value was derived through integration and this mean value was used to assess the Na concentration. The results are shown in Table 1.

Photoelectric conversion efficiency was also assessed for the photoelectric conversion elements of working examples 1 to 10 and comparison example 1.

The fabricated photoelectric conversion element was then assessed for photoelectric conversion efficiency using artificial sun light of 100 mW/cm² and an air mass (AM) of 1.5.

Eight samples of each of the respective photoelectric conversion elements of working examples 1 to 10 and comparison example 1 were fabricated. Then, the respective photoelectric conversion efficiencies of working examples 1 to 10 and comparison example 1 were measured, and those having a photoelectric conversion efficiency of 80% or higher with respect to the maximum value were assessed as acceptable products, and all others as unacceptable products. The mean value of the acceptable products was then regarded as the conversion efficiency of the respective photoelectric conversion elements of working examples 1 to 10 and comparison example 1. The results are shown in Table 1.

In this example 1, a film (Mo—Na film) of Mo containing Na₂MoO₄, serving as alkali supply layer (Na supply source), was formed. The film deposition rate was 300 nm/minute. The film deposition rate was 4 nm/minute in the case when a soda lime layer used as the alkali supply layer was formed under the film deposition conditions of power density of 2 W/cm², deposition pressure of 1.2 Pa (in argon and oxygen atmosphere) using an RF power source and a soda lime glass target of target size (diameter) 8 inches.

The Mo—Na film formed as the alkali supply layer in this example 1 had a film deposition rate that is 75 times of that the soda lime layer.

In this example 1, the sheet resistance of the Mo—Na films of the alkali supply layers (as the Na supply source) were measured for working examples that have different thickness in the back electrodes including working example 1 (thickness 800 nm), working example 7 (thickness 400 nm), and working example 10 (thickness 200 nm). The results too are shown in Table 1.

TABLE 1

| | Diffusion | | | Na Concentration | Conversion | | |
|---|---|---|---|---|---|---|---|
| | Prevention | Alkali Supply | Back | of CIGS Layer | Efficiency | Sheet | |
| | Layer | Layer | Electrode | (atoms/cm³) | (%) | Resistance | Remarks |
| Working | AlN | Mo—Na: 400 nm | Mo: 800 nm | 4 × 10¹⁹ | 16.5 | 0.11 Ω/□ | |
| Example 1 | | | | | | | |
| Working | TiN | Mo—Na: 400 nm | Mo: 800 nm | 9 × 10¹⁸ | 16.1 | | |
| Example 2 | | | | | | | |
| Working | ZrN | Mo—Na: 400 nm | Mo: 800 nm | 1 × 10¹⁹ | 16.0 | | |
| Example 3 | | | | | | | |
| Working | AlN | Mo—Na: 200 nm | Mo: 800 nm | 4 × 10¹⁸ | 15.2 | | |
| Example 4 | | | | | | | |
| Working | AlN | Mo—Na: 800 nm | Mo: 800 nm | 3 × 10¹⁹ | 15.8 | | |
| Example 5 | | | | | | | |
| Working | AlN | Mo—Na: 200 nm | Mo: 400 nm | 8 × 10¹⁸ | 15.6 | | |
| Example 6 | | | | | | | |
| Working | AlN | Mo—Na: 400 nm | Mo: 400 nm | 5 × 10¹⁹ | 16.7 | 0.22 Ω/□ | |
| Example 7 | | | | | | | |
| Working | TiO₂ | Mo—Na: 400 nm | Mo: 800 nm | 1 × 10¹⁸ | 13.2 | | |
| Example 8 | | | | | | | |
| Working | Al₂O₃ | Mo—Na: 400 nm | Mo: 800 nm | 8 × 10¹⁷ | 14.1 | | |
| Example 9 | | | | | | | |
| Working | AlN | Mo—Na: 400 nm | Mo: 200 nm | 5 × 10¹⁹ | 16.5 | 0.35 Ω/□ | |
| Example 10 | | | | | | | |
| Comparison | None | Mo—Na: 400 nm | Mo: 800 nm | 1 × 10¹⁷ | 12.1 | | * |
| Example 1 | | | | | | | |

As shown in Table 1 above, a comparison of working examples 1 to 7 and comparison example 1 shows that those examples with a diffusion prevention layer have an increased Na concentration within the CIGS layer. Accordingly, the conversion efficiency shows improvement as well.

In comparison example 1, among the 8 photoelectric conversion element samples manufactured, more than half were disqualified products (marked with a “*” in Table 1). The high percentage of the disqualified products in comparison example 1 is caused by the excessive Na diffused to the substrate.

When working examples 1 to 7 were compared with working examples 8 and 9, the Na concentration in the CIGS layer was higher in the case of the nitride diffusion prevention layer than in the case of the oxide diffusion prevention layer. Thus, the effect of diffusing alkali metal into the CIGS layer was higher in the case of the nitride diffusion prevention layer than in the case of the oxide diffusion prevention layer.

Here, it is believed that while the oxide film prevents diffusion into the substrate by including Na therein, the nitride does not readily contain an alkali metal such as Na within the film and thus inhibits diffusion into the nitride film, thereby promoting Na diffusion to the CIGS layer that is an upper layer above the alkali supply layer. From this fact it is believed that a larger amount of Na is diffused in the upper CIGS layer in the case of a nitride diffusion prevention layer.

Further, a comparison of working examples 1 to 3 does not reveal much of a difference between the examples. Of the nitride diffusion prevention layers, AlN, TiN, and ZrN all seem to have the same effects of preventing alkali metal diffusion to the substrate and diffusing Na to the CIGS layer.

Further, a comparison of working example 1 and working examples 4 to 7 reveals that, when a nitride diffusion prevention layer is used, with an Mo—Na film (of the alkali supply layer or Na supply source) having a thickness of 200 nm, conversion efficiency can be sufficiently improved. However, since the degree of improvement was higher when the alkali supply layer (Mo—Na film) was 400 nm, as in working examples 1 and 7, it is preferred that the alkali supply layer (Mo—Na film) is 400 nm.

Further, a comparison of working examples 1 and 7 and working examples 4 and 6 reveals that the Na concentration in the CIGS layer can also be increased by reducing the thickness of the Mo film of the back electrodes.

Further, as can be seen from the comparison of the sheet resistances of working examples 1, 7 and 10, if the thickness of the Mo film, which serves as the back electrode, is 200 nm, it can function sufficiently as a back electrode because of the conductivity of the Mo—Na film.

As mentioned above, if a Mo—Na film is used as the alkali supply layer, the film deposition rate can be 75 times of that of a soda lime layer. Therefore, it is obvious that the productivity of the photoelectric conversion element can be increased.

### Example 2

In this example 2, the insulation characteristics of working example 1 and comparison example 1 were assessed.

In this example 2, when measuring insulation characteristics, Au electrodes 3.5 mm in diameter and 0.2 μm thick were formed by masked vapor deposition on top of the diffusion prevention layer (aluminum nitride film) in working example 1, and on top of the anodized film in comparison example 1. Then, with the Au electrodes serving as a negative pole, a voltage of 200 V was applied between the metal substrate and Au electrodes, and the leakage current that flowed between the metal substrate and Au electrodes was measured at the time the voltage was applied. The leakage current density was then found by dividing the detected leakage current by the Au electrode surface area (9.6 mm²). This leakage current density was then used to assess the insulation properties.

Table 2 below shows the measurement results (leakage current densities) of the insulation properties of working example 1 and comparison example 1.

TABLE 2

| | | Leakage Current Density |
|---|---|---|
| | Layer Structure | (μA/cm²) |
| Working Example 1 | AlN/Substrate | 0.08 |
| Comparison Example 1 | Substrate | 0.72 |

As shown in Table 2 above, it is seen that working example 1, which has the diffusion prevention layer made of the insulator aluminum nitride, exhibits superior insulation properties.

What is claimed is:

1. A photoelectric conversion element comprising:
a substrate with an insulation layer comprising a metallic substrate and an electrical insulation layer formed on a surface of said metallic substrate;
a diffusion prevention layer formed on said electrical insulation layer;
an alkali supply layer being electrically conductive and formed on said diffusion prevention layer;
a lower electrode formed on said alkali supply layer;
a photoelectric conversion layer comprising a compound semiconductor layer and formed on said lower electrode; and
an upper electrode formed on said photoelectric conversion layer,
wherein said diffusion prevention layer prevents at least diffusion of alkali metal from said alkali supply layer to said substrate with the insulation layer.

2. The photoelectric conversion element according to claim 1, wherein said compound semiconductor comprises at least one kind of compound semiconductor of a chalcopyrite structure.

3. The photoelectric conversion element according to claim 2, wherein said compound semiconductor is composed of at least one kind of compound semiconductor comprising a group Ib element, a group IIIb element, and a group VIb element.

4. The photoelectric conversion element according to claim 3, wherein said group Ib element is composed of at least one selected from the group consisting of Cu and Ag, said group IIIb element is composed of at least one selected from the group consisting of Al, Ga, and In, and said group VIb element is composed of at least one selected from the group consisting of S, Se, and Te.

5. The photoelectric conversion element according to claim 1, wherein said diffusion prevention layer is made of nitride.

6. The photoelectric conversion element according to claim 5, wherein said nitride is an electrical insulator.

7. The photoelectric conversion element according to claim 5, wherein said nitride comprises at least one of TiN, ZrN, BN, and AlN.

8. The photoelectric conversion element according to claim 7, wherein said nitride is composed of AlN.

9. The photoelectric conversion element according to claim 1, wherein said diffusion prevention layer has a thickness of 10 nm to 200 nm.

10. The photoelectric conversion element according to claim 9, wherein said thickness of said diffusion prevention layer ranges from 10 nm to 100 nm.

11. The photoelectric conversion element according to claim 1, wherein said photoelectric conversion layer is split into plural elements by plural opening grooves, and said plural elements is electrically connected in series.

12. The photoelectric conversion element according to claim 1, wherein said alkali supply layer comprises a Mo layer that contains Na and/or an Na compound.

13. The photoelectric conversion element according to claim 12, wherein said Na compound comprises NaF or Na₂MoO₄.

14. The photoelectric conversion element according to claim 1, wherein said alkali supply layer comprises a layer formed by sputtering.

15. The photoelectric conversion element according to claim 1, wherein said alkali supply layer has a thickness of 100 nm to 800 nm.

16. The photoelectric conversion element according to claim 1, wherein said lower electrode is made of Mo, and has a thickness of 200 nm to 600 nm.

17. The photoelectric conversion element according to claim 16, wherein said thickness of said lower electrode ranges from 200 nm to 400 nm.

18. The photoelectric conversion element according to claim 1, wherein said metallic substrate comprises a laminated plate wherein a metal base and an Al base are laminated and unified.

19. The photoelectric conversion element according to claim 18, wherein said laminated plate laminates and integrates said metal base and said Al base by compression bonding.

20. The photoelectric conversion element according to claim 18, wherein said metal base comprises a steel material, an alloy steel material, a Ti foil, or a dual-layer base composed of the Ti foil and the steel material.

21. The photoelectric conversion element according to claim 20, wherein said alloy steel material is made of carbon steel or ferrite stainless steel.

22. The photoelectric conversion element according to claim 18, wherein a difference between a linear thermal expansion coefficient of said metal base and that of said photoelectric conversion layer is less than 3×10⁻⁶/° C.

23. The photoelectric conversion element according to claim 22, wherein said difference between the linear thermal expansion coefficient of said metal base and that of said photoelectric conversion layer is less than 1×10⁻⁶/° C.

24. The photoelectric conversion element according to claim 1, wherein said metallic substrate comprises a laminated plate wherein an alloy steel material made of ferrite stainless steel or carbon steel is integrated with an Al base by compression bonding, said lower electrode is made of Mo, and said photoelectric conversion layer is a layer comprising as a main component at least one kind of compound semiconductor comprising a group Ib element, a group IIIb element, and a group VIb element.

25. The photoelectric conversion element according to claim 1, wherein said electrical insulation layer comprises an anodized film of aluminum.

26. The photoelectric conversion element according to claim 1, wherein said anodized film has a porous structure.

27. A thin-film solar cell comprising the photoelectric conversion element according to claim 1.

28. A method of manufacturing a photoelectric conversion element, comprising:
forming an electrical insulation layer on a surface of a metallic substrate to obtain a substrate with an insulation layer;
forming, on said electrical insulation layer, a diffusion prevention layer that prevents at least diffusion of an alkali metal into said substrate with the insulation layer;
forming a conductive alkali supply layer on said diffusion prevention layer;
forming a lower electrode on said conductive alkali supply layer;
forming a photoelectric conversion layer on said lower electrode; and
forming an upper electrode on said photoelectric conversion layer.

29. The manufacturing method according to claim 28, wherein said metallic substrate is a laminated plate wherein a metal base and an Al base are laminated and unified, and said forming step of said electrical insulation layer is a step of subjecting said Al base to an anodizing treatment to form an anodized film on a surface of said Al base.
